(19) United States
(12) Patent Application Publication
(10) Pub. No.: US 2026/0193493 A1
(43) Pub. Date: Jul. 9, 2026

(54) ADHESIVE COMPOSITION AND ADHESIVE SHEET

(71) Applicant: Resonac Corporation, Tokyo (JP)

(72) Inventors: Koji NAODA, Tokyo (JP); Keita YUMOTO, Tokyo (JP); Kazuhiro SASAKI, Tokyo (JP)

(73) Assignee: Resonac Corporation, Tokyo (JP)

(21) Appl. No.: 19/132,242

(22) PCT Filed: Oct. 4, 2023
(86) PCT No.: PCT/JP2023/036165

§ 371 Date: May 22, 2025

(30) Foreign Application Priority Data
Dec. 6, 2022 (JP) 2022-194968

(51) Int. Cl. C09J 7/38; H10P 58/00; H10P 72/70

(52) U.S. Cl. CPC C09J 7/385; H10P 58/00; H10P 72/7402; C09J 2203/326; C09J 2301/302; C09J 2301/414; C09J 2301/416

(57) ABSTRACT

An adhesive composition contains a (meth)acrylic resin (A), a photopolymerization initiator (B), and a crosslinking agent (C), wherein the (meth)acrylic resin (A) contains structural units of formulas (2) and (3). In formula (2), R³ represents hydrogen or a methyl group, and R⁴ represents a group having a hydroxy group on a first carbon atom and having, on a second carbon atom adjacent to the first carbon atom, a residue removed of a hydrogen atom from a carboxy group of an unsaturated monocarboxylic acid. In formula (3), R⁵ represents hydrogen or a methyl group, and R⁶ represents a group having, on a first carbon atom, a residue removed of a hydrogen atom from a carboxy group of an unsaturated monocarboxylic acid and having, on a second carbon atom adjacent to the first carbon atom, a residue removed of a hydrogen atom from a carboxy group of an unsaturated monocarboxylic acid.

### TECHNICAL FIELD

The content of the present disclosure relates to a pressure sensitive adhesive composition containing a (meth)acrylic resin, a pressure sensitive adhesive sheet, and a dicing/die-bonding integrated film.

### BACKGROUND ART

Various pressure sensitive adhesive sheets have been known and used in semiconductor manufacturing processes and the like. Specific examples include a protective sheet (back grinding tape) for protecting a semiconductor wafer in a back grinding step of the semiconductor wafer, and a fixing sheet (dicing tape) used in a cutting and separating (dicing) step of a semiconductor wafer into small element pieces. These pressure sensitive adhesive sheets are removable pressure sensitive adhesive sheets that are attached to a semiconductor wafer, an adherend, and released from the adherend after predetermined processing steps have been completed.

A known pressure sensitive adhesive composition used in a pressure sensitive adhesive layer of a removable pressure sensitive adhesive sheet includes one having a resin, the resin including a (meth)acrylic resin in which an UV (ultraviolet) curable ethylenically unsaturated group is introduced into a side chain. Such a pressure sensitive adhesive composition undergoes a crosslinking reaction upon UV irradiation and cures, which leads to a reduction in adhesive strength. For example, Patent Literature 1 (JP 2014-062210 A) describes a method for producing a pressure sensitive adhesive sheet including a step of reacting a (meth)acrylic polymer having two or more hydroxy groups in a side chain with a compound having an isocyanate group such as 2-isocyanatoethyl (meth)acrylate in the presence of a first catalyst to form a (meth)acrylic polymer having a urethane bond.

### CITATION LIST

### Patent Literature

PTL 1: JP 2014-062210 A

### SUMMARY OF INVENTION

### Technical Problem

Among the removable pressure sensitive adhesive sheets, a dicing tape included in a dicing/die-bonding integrated film, in which a dicing tape and a die bond (adhesive layer) are integrated, is required to have a high adhesive strength to the adhesive layer and have a characteristic that allows it to be easily released from the adhesive layer without adhesive residue after UV irradiation, which are not required for other removable pressure sensitive adhesive sheets. However, when an ethylenically unsaturated group is introduced into a side chain of a (meth)acrylic resin using a compound having an isocyanate group as in Patent Literature 1, there is an issue that a dimer of an isocyanate compound is generated as an impurity during synthesis, and this dimer adversely affects a reduction in adhesive strength after UV (ultraviolet) curing. As a result, release property from the adhesive layer after completion of the processing steps is insufficient, and thus improvement of this is desired. The present disclosure provides a pressure sensitive adhesive composition which has a sufficient adhesive strength to an adherend such as an adhesive layer and has improved release property from the adherend in which the adhesive strength is sufficiently reduced upon UV irradiation after completion of the processing steps.

### Solution to Problem

The content of the present disclosure includes the following aspects.

[1]

An pressure sensitive adhesive composition, comprising:
a (meth)acrylic resin (A);
a photopolymerization initiator (B); and
a crosslinking agent (C),
the (meth)acrylic resin (A) containing structural units represented by the following Formulas (1) to (3) and optionally containing a structural unit represented by the following Formula (4):

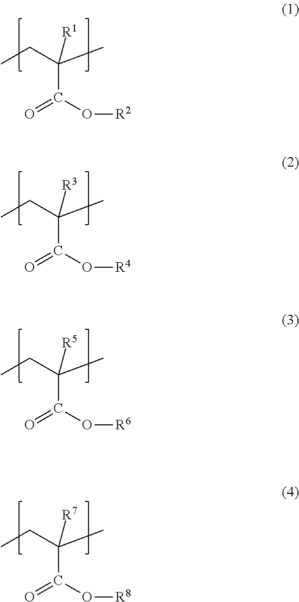

wherein in Formula (1), R¹ represents a hydrogen atom or a methyl group, and R² represents an alkyl group having from 1 to 20 carbon atoms, in Formula (2), R³ represents a hydrogen atom or a methyl group, and R⁴ represents a group having: a hydroxy group bonded to a carbon atom; and a residue bonded to a carbon atom adjacent to said carbon atom, the residue being obtained by removing a hydrogen atom from a carboxy group of an unsaturated monocarboxylic acid, in Formula (3), R⁵ represents a hydrogen atom or a methyl group, and R⁶ represents a group having: a residue bonded to a carbon atom, the residue being obtained by removing a hydrogen atom from a carboxy group of an unsaturated monocarboxylic acid; and a residue bonded to a carbon atom adjacent to said carbon atom, the residue being obtained by removing a hydrogen atom from a carboxy group of an unsaturated monocarboxylic acid, and in Formula (4), R⁷ represents a hydrogen atom or a methyl group, and R⁸ represents a group containing an epoxy group.
   [2]

The pressure sensitive adhesive composition according to aspect [1], wherein an ethylenically unsaturated group equivalent of the (meth)acrylic resin (A) is from 350 to 4000 g/mol.

[3]

The pressure sensitive adhesive composition according to aspect [1] or [2], wherein a percentage of a total of the structural units represented by Formulas (2) to (4), based on all the structural units of the (meth)acrylic resin (A), is from 1 to 50 mol %.

[4]

The pressure sensitive adhesive composition according to any one of aspects [1] to [3], wherein a percentage of a total of the structural units represented by Formulas (2) and (3) of the (meth)acrylic resin (A), relative to a total of the structural units represented by Formulas (2) to (4), is from 50 to 100 mol %.

[5]

The pressure sensitive adhesive composition according to any one of aspects [1] to [4], wherein a glass transition temperature (Tg) of the (meth)acrylic resin (A) is from −80° C. to 0° C.

[6]

The pressure sensitive adhesive composition according to any one of aspects [1] to [5], wherein the residue obtained by removing a hydrogen atom from a carboxy group of an unsaturated monocarboxylic acid is a (meth)acryloyloxy group.

[7]

The pressure sensitive adhesive composition according to any one of aspects [1] to [6], wherein each of the carbon atoms, to which the hydroxy group or the residue obtained by removing a hydrogen atom from a carboxy group of an unsaturated monocarboxylic acid is bonded in Formulas (2) and (3) has one or two hydrogen atoms.

[8]

The pressure sensitive adhesive composition according to any one of aspects [1] to [7], wherein a hydroxyl value of the (meth)acrylic resin (A) is from 1 to 60 mgKOH/g.

[9]

The pressure sensitive adhesive composition according to any one of aspects [1] to [8], wherein a weight average molecular weight of the (meth)acrylic resin (A) is from 100000 to 1000000.

[10]

The pressure sensitive adhesive composition according to any one of aspects [1] to [9], wherein the crosslinking agent (C) is a polyisocyanate.

[11]

An ultraviolet curable pressure sensitive adhesive layer, which is a thermally cured product of the pressure sensitive adhesive composition according to any one of aspects [1] to [10].

[12]

A pressure sensitive adhesive sheet, comprising:
the ultraviolet curable pressure sensitive adhesive layer according to aspect [11]; and
a substrate layer.
   [13]

A dicing/die-bonding integrated film, comprising:
a substrate layer, the ultraviolet curable pressure sensitive adhesive layer according to aspect [11], and an adhesive layer in this order.
   [14]

A method for manufacturing a semiconductor device, the method comprising dicing a semiconductor by using the dicing/die-bonding integrated film according to aspect [13].

### Advantageous Effects of Invention

According to the present disclosure, it is possible to provide a pressure sensitive adhesive composition having an excellent adhesive strength and an excellent release property when a pressure sensitive adhesive sheet is released from an adherend after UV irradiation.

### DESCRIPTION OF EMBODIMENTS

Hereinafter, embodiments of the present invention will be described in detail. However, the present invention is not limited to the embodiments described below.

In the present specification, when “to” is used for a numerical range, the numerical values at both ends are an upper limit value and a lower limit value, respectively, and are included in the numerical range.

In the present specification, the term “(meth)acrylic” means “acrylic” or “methacrylic”, the term “(meth)acrylate” means “acrylate” or “methacrylate”, and the term “(meth)acryloyloxy” means “acryloyloxy” or “methacryloyloxy”.

In the present specification, the “structural unit” means a unit derived from a polymerizable compound used as a monomer or a unit obtained by further modifying a unit derived from a polymerizable compound used as a monomer.

### Pressure Sensitive Adhesive Composition

A pressure sensitive adhesive composition in an embodiment contains a (meth)acrylic resin (A), a photopolymerization initiator (B), and a crosslinking agent (C).

### (Meth)Acrylic Resin (A)

The (meth)acrylic resin (A) in an embodiment contains structural units represented by the following Formulas (1) to (3) and optionally contains a structural unit represented by the following Formula (4).

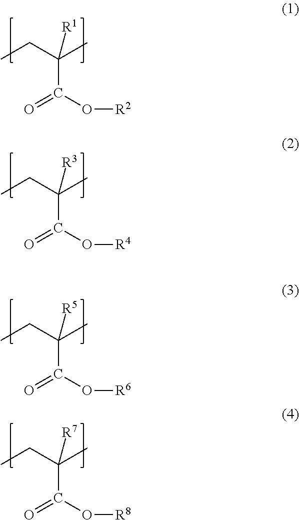

In Formula (1), R¹ represents a hydrogen atom or a methyl group, and R² represents an alkyl group having from 1 to 20 carbon atoms, in Formula (2), R³ represents a hydrogen atom or a methyl group, and R⁴ represents a group having: a hydroxy group bonded to a carbon atom; and a residue bonded to a carbon atom adjacent to said carbon atom, the residue being obtained by removing a hydrogen atom from a carboxy group of an unsaturated monocarboxylic acid, in Formula (3), R⁵ represents a hydrogen atom or a methyl group, and R⁶ represents a group having: a residue bonded to a carbon atom, the residue being obtained by removing a hydrogen atom from a carboxy group of an unsaturated monocarboxylic acid; and a residue bonded to a carbon atom adjacent to said carbon atom, the residue being obtained by removing a hydrogen atom from a carboxy group of an unsaturated monocarboxylic acid, and in Formula (4), R⁷ represents a hydrogen atom or a methyl group, and R⁸ represents a group containing an epoxy group.

### Structural Unit Represented by Formula (1)

The (meth)acrylic resin (A) contains a structural unit of the following Formula (1). The structural unit represented by Formula (1) contributes to imparting adhesive strength.

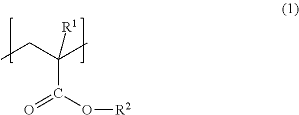

In Formula (1), R¹ represents a hydrogen atom or a methyl group, and R² represents an alkyl group having from 1 to 20 carbon atoms. R² is preferably a linear or branched chain alkyl group, more preferably a linear or branched chain alkyl group having from 1 to 10 carbon atoms, and still more preferably a linear or branched chain alkyl group having from 4 to 8 carbon atoms. The structural unit represented by Formula (1) does not have to be of one type. R¹ in each structural unit may be different from one another, and R² in each structural unit may also be different from one another.

Specific examples of monomers from which the structural unit represented by Formula (1) is derived include alkyl (meth)acrylates, such as methyl (meth)acrylate, ethyl (meth)acrylate, butyl (meth)acrylate, hexyl (meth)acrylate, 2-ethylhexyl (meth)acrylate, and decyl (meth)acrylate. Among these, from the perspective of ease of synthesis of the (meth)acrylic resin (A) and the adhesive property as well as the release property after UV irradiation, methyl (meth)acrylate, ethyl (meth)acrylate, butyl (meth)acrylate, and 2-ethylhexyl (meth)acrylate are preferable, and from the perspective of release property after UV irradiation, 2-ethylhexyl (meth)acrylate is more preferable.

The monomers from which the structural unit represented by Formula (1) is derived may be used singly or in combination of two or more kinds thereof.

The percentage of the structural unit represented by Formula (1), relative to all the structural units of the (meth)acrylic resin (A), is preferably from 50 to 99 mol %, more preferably from 60 to 98 mol %, and still more preferably from 70 to 95 mol %. When the structural unit represented by Formula (1) is 50 mol % or more, sufficient pressure sensitive adhesiveness to an adherend can be obtained before UV irradiation. When the structural unit represented by Formula (1) is 99 mol % or less, a sufficient percentage of the structural units represented by Formulas (2) and (3) described later can be secured, so that sufficient photocurability as a pressure sensitive adhesive composition and thus desired release property after UV irradiation can be obtained.

### Structural Unit Represented by Formula (2)

The (meth)acrylic resin (A) contains a structural unit represented by the following Formula (2). This allows a hydroxy group portion to be crosslinked with the crosslinking agent (C), and thus an ultraviolet curable pressure sensitive adhesive layer can be formed by thermal curing. The ethylenically unsaturated group introduced into the side chain can impart the photocurability to the pressure sensitive adhesive composition, reduce the adhesive strength after UV irradiation, and improve the release property from an adherend.

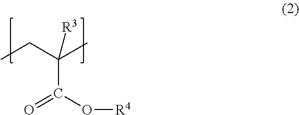

In Formula (2), R³ represents a hydrogen atom or a methyl group, and R⁴ represents a group having: a hydroxy group bonded to a carbon atom; and a residue bonded to a carbon atom adjacent to said carbon atom, the residue being obtained by removing a hydrogen atom from a carboxy group of an unsaturated monocarboxylic acid. From the perspective of heat resistance, the carbon atom to which the hydroxy group is bonded preferably has one hydrogen atom, and the carbon atom to which the residue obtained by removing a hydrogen atom from a carboxy group of an unsaturated monocarboxylic acid is bonded preferably has one or two hydrogen atoms. The structural unit represented by Formula (2) does not have to be of one type. R³ in each structural unit may be different from one another, and R⁴ in each structural unit may also be different from one another.

Specific examples of the residue obtained by removing a hydrogen atom from a carboxy group of an unsaturated monocarboxylic acid constituting R⁴ include residues obtained by removing a hydrogen atom from a carboxy group of the following unsaturated monocarboxylic acids, such as (meth)acrylic acid, 2-(meth)acryloyloxyethylsuccinic acid, 2-(meth)acryloyloxyethylhexahydrophthalic acid, crotonic acid, propiolic acid, cinnamic acid, monomethyl maleate, monoethyl maleate, monoisopropyl maleate, monomethyl fumarate, and monoethyl itaconate. Among these, from the perspective of ease of synthesis of the (meth)acrylic resin, the residue obtained by removing a hydrogen atom from a carboxy group of (meth)acrylic acid, that is, a (meth)acryloyloxy group is preferable.

Specific examples of the structural unit represented by Formula (2) include structural units represented by the following Formula (2-1-1) and the following Formula (2-1-2).

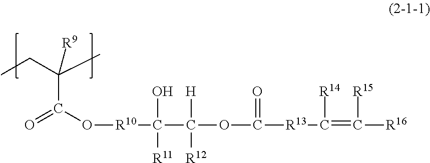

In Formula (2-1-1), R⁹ represents a hydrogen atom or a methyl group, R¹⁰ represents a divalent linking group, R¹, R¹², R¹⁴ and R¹⁵ each independently represent a hydrogen atom or an alkyl group having from 1 to 6 carbon atoms, R¹³ represents a single bond or a divalent linking group, and R¹⁶ represents a hydrogen atom, an alkyl group having from 1 to 6 carbon atoms, —COOR (where R represents an alkyl group having from 1 to 6 carbon atoms), or a phenyl group.

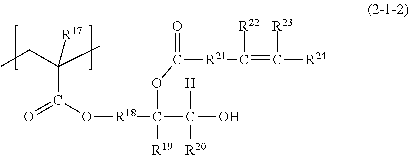

In Formula (2-1-2), R¹⁷ represents a hydrogen atom or a methyl group, R¹⁸ represents a divalent linking group, R¹⁹, R²⁰, R²² and R²³ each independently represent a hydrogen atom or an alkyl group having from 1 to 6 carbon atoms, R²¹ represents a single bond or a divalent linking group, and R²⁴ represents a hydrogen atom, an alkyl group having from 1 to 6 carbon atoms, —COOR (where R represents an alkyl group having from 1 to 6 carbon atoms), or a phenyl group.

In Formula (2-1-1), examples of the divalent linking group represented by R¹⁰ include an alkylene group having from 1 to 20 carbon atoms and —R⁵⁵—O—R⁵⁶— (where R⁵⁵ and R⁵⁶ each independently represent an alkylene group having from 1 to 10 carbon atoms). Examples of the alkylene group having from 1 to 20 carbon atoms represented by R¹⁰ include a methylene group, an ethylene group, and a butylene group. Among these, from the perspective of adhesiveness to an adherend, an alkylene group having from 1 to 10 carbon atoms is preferable, and a methylene group and an ethylene group are more preferable. Examples of the alkylene group having from 1 to 10 carbon atoms represented by R⁵⁵ and R⁵⁶ include a methylene group, an ethylene group, and a butylene group. Among these, an alkylene group having from 1 to 6 carbon atoms is preferable from the perspective of photocurability. For R¹⁰, an alkylene group having from 1 to 10 carbon atoms and —R⁵⁵—O—R⁵⁶— are preferable, and a methylene group, an ethylene group, and —(CH₂)ₙ—O—(CH₂)_{y}— (where n is an integer from 1 to 6, and y is an integer from 1 to 2) are more preferable. n is preferably an integer from 2 to 6, and y is preferably an integer from 1 to 2.

In Formula (2-1-1), R^{D}, R¹², R¹⁴, and R¹⁵ each independently represent a hydrogen atom or an alkyl group having from 1 to 6 carbon atoms. Examples of the alkyl group having from 1 to 6 carbon atoms represented by R¹, R¹², R¹⁴, and R¹⁵ include a methyl group. From the perspective of heat resistance, both R¹¹ and R¹² are preferably a hydrogen atom. From the perspective of heat resistance, R¹⁴ is preferably a hydrogen atom or a methyl group. From the perspective of photocurability, R¹⁵ is preferably a hydrogen atom.

In Formula (2-1-1), R¹³ represents a single bond or a divalent linking group. Examples of the divalent linking group include an alkylene group having from 1 to 20 carbon atoms, —R⁵⁷—O—R⁵⁸— (where R⁵⁷ and R⁵⁸ each independently represent an alkylene group having from 1 to 10 carbon atoms), —R⁵⁹—CO—O—R⁶⁰—CO—, and —R⁶¹—CO—O—R⁶²— (where R⁵⁹ to R⁶² each independently represent an alkylene group having from 1 to 10 carbon atoms). Examples of the alkylene group having from 1 to 20 carbon atoms represented by R¹³ include a methylene group, an ethylene group, and a butylene group. For R¹³, from the perspective of photocurability, a single bond and an alkylene group having from 1 to 6 carbon atoms are preferable, and a single bond is more preferable.

In Formula (2-1-1), R¹⁶ represents a hydrogen atom, an alkyl group having from 1 to 6 carbon atoms, —COOR (where R represents an alkyl group having from 1 to 6 carbon atoms), or a phenyl group. Examples of the alkyl group having from 1 to 6 carbon atoms represented by R¹⁶ include a methyl group and an ethyl group. From the perspective of photocurability, R¹⁶ is preferably a hydrogen atom.

In Formula (2-1-2), specific examples and preferable examples of R¹⁸ to R²⁴ are the same as those of R¹⁰ to R¹⁶ in Formula (2-1-1), respectively.

Specific examples of a method for deriving the structural unit represented by Formula (2-1-1) or Formula (2-1-2) include a method in which a structural unit represented by Formula (4-1) described later is introduced, and then a carboxy group of an unsaturated monocarboxylic acid is reacted with an epoxy group of Formula (4-1) to introduce a residue obtained by removing a hydrogen atom from the carboxy group of the unsaturated monocarboxylic acid. The monomers from which the structural unit represented by Formula (4-1) is derived may be used singly or in combination of two or more kinds thereof, and the unsaturated monocarboxylic acid to be reacted may be used singly or in combination of two or more kinds thereof.

Specific examples of the structural unit represented by Formula (2) include structural units represented by the following Formula (2-2).

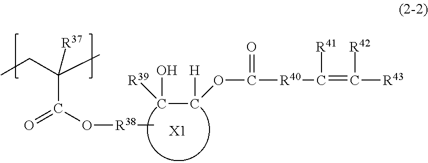

In Formula (2-2), R³⁷ represents a hydrogen atom or a methyl group, R³⁸ represents a single bond or a divalent linking group, R³⁹, R⁴¹ and R⁴² each independently represent a hydrogen atom or an alkyl group having from 1 to 6 carbon atoms, R⁴⁰ represents a single bond or a divalent linking group, R⁴³ represents a hydrogen atom, an alkyl group having from 1 to 6 carbon atoms, —COOR (where R represents an alkyl group having from 1 to 6 carbon atoms) or a phenyl group, and X1 represents a saturated hydrocarbon ring.

Examples of the divalent linking group represented by R³⁸ include an alkylene group having from 1 to 20 carbon atoms, —R⁶³—O—R⁶⁴— (where R⁶³ and R⁶⁴ each independently represent an alkylene group having from 1 to 10 carbon atoms), —R⁶⁵—O— (where R⁶⁵ represents an alkylene group having from 1 to 10 carbon atoms), —COO—, and combinations thereof. Examples of the alkylene group having from 1 to 20 carbon atoms constituting R³⁸ include a methylene group, an ethylene group, a butylene group, and a cyclohexylene group. Among these, from the perspective of adhesiveness to an adherend, an alkylene group having from 1 to 10 carbon atoms is preferable, and a methylene group and an ethylene group are more preferable. Examples of the alkylene group having from 1 to 10 carbon atoms represented by R⁶³ and R⁶⁴ include a methylene group, an ethylene group, and a butylene group. Among these, an alkylene group having from 1 to 6 carbon atoms is preferable from the perspective of photocurability. Examples of the alkylene group having from 1 to 10 carbon atoms represented by R⁶⁵ include a methylene group, an ethylene group, and a butylene group. Among these, an alkylene group having from 1 to 6 carbon atoms is preferable from the perspective of photocurability. R³⁸ is preferably a single bond, an alkylene group having from 1 to 10 carbon atoms, or —R⁶⁵—O—, and more preferably a single bond, a methylene group, an ethylene group, or —(CH₂)ₘ—O— (where m is an integer from 1 to 3).

In Formula (2-2), R³⁹, R⁴¹, and R⁴² each independently represent a hydrogen atom or an alkyl group having from 1 to 6 carbon atoms. Examples of the alkyl group having from 1 to 6 carbon atoms represented by R³⁹, R⁴¹, and R⁴² include a methyl group. From the perspective of heat resistance, R³⁹ is preferably a hydrogen atom. From the perspective of heat resistance, R⁴¹ is preferably a hydrogen atom or a methyl group. From the perspective of photocurability, R⁴² is preferably a hydrogen atom.

In Formula (2-2), specific examples and preferable examples of R⁴⁰ and R⁴³ are the same as those of R¹³ and R¹⁶ in Formula (2-1-1), respectively.

In Formula (2-2), X1 represents a saturated hydrocarbon ring. The number of carbon atoms in the saturated hydrocarbon ring is preferably from 4 to 20, more preferably from 5 to 10, and still more preferably from 5 to 8. The saturated hydrocarbon ring may be a single ring or a fused ring.

The saturated hydrocarbon ring is preferably a cyclohexyl group, a cyclopentyl group, or a tricyclodecanyl group.

From the perspective of heat resistance, the structural unit represented by Formula (2) preferably contains the structural unit represented by Formula (2-2).

Specific examples of a method for deriving the structural unit represented by Formula (2-2) include a method in which a structural unit represented by Formula (4-2) described later is introduced, and then a carboxy group of an unsaturated monocarboxylic acid is reacted with an epoxy group of Formula (4-2) to introduce a residue obtained by removing a hydrogen atom from the carboxy group of the unsaturated monocarboxylic acid. The monomers from which the structural unit represented by Formula (4-2) is derived may be used singly or in combination of two or more kinds thereof, and the unsaturated monocarboxylic acid to be reacted may be used singly or in combination of two or more kinds thereof.

The percentage of the structural unit represented by Formula (2), relative to all the structural units of the (meth)acrylic resin (A), is preferably from 0.1 to 40 mol %, more preferably from 0.5 to 18 mol %, and still more preferably from 1 to 15 mol %. When the structural unit represented by Formula (2) is 0.1 mol % or more, a thermosetting property of the pressure sensitive adhesive composition is sufficient. As a result, a sufficient adhesive strength to an adherend and a sufficient cohesive strength of the pressure sensitive adhesive composition are obtained. When the structural unit represented by Formula (2) is 40 mol % or less, a sufficient percentage of the structural unit represented by Formula (1) can be secured, and a good adhesive strength can be obtained.

### Structural Unit Represented by Formula (3)

The (meth)acrylic resin (A) contains a structural unit represented by the following Formula (3). Two ethylenically unsaturated groups introduced into a side chain can impart the photocurability to the pressure sensitive adhesive composition, reduce the adhesive strength of the pressure sensitive adhesive composition after UV irradiation, and improve the release property from an adherend.

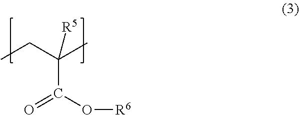

In Formula (3), R⁵ represents a hydrogen atom or a methyl group, and R⁶ represents a group having: a residue bonded to a carbon atom, the residue being obtained by removing a hydrogen atom from a carboxy group of an unsaturated monocarboxylic acid; a residue bonded to a carbon atom adjacent to said carbon atom, the residue being obtained by removing a hydrogen atom from a carboxy group of an unsaturated monocarboxylic acid. From the perspective of heat resistance, each carbon atom having the residue obtained by removing a hydrogen atom from a carboxy group of an unsaturated monocarboxylic acid preferably has one or two hydrogen atoms. The structural unit represented by Formula (3) does not have to be of one type. R⁵ in each structural unit may be different from one another, and R⁶ in each structural unit may also be different from one another.

Specific examples of the residue obtained by removing a hydrogen atom from a carboxy group of an unsaturated monocarboxylic acid constituting R⁶ include residues obtained by removing a hydrogen atom from a carboxy group of the following unsaturated monocarboxylic acids, such as (meth)acrylic acid, 2-(meth)acryloyloxyethylsuccinic acid, 2-(meth)acryloyloxyethylhexahydrophthalic acid, crotonic acid, propiolic acid, cinnamic acid, monomethyl maleate, monoethyl maleate, monoisopropyl maleate, monomethyl fumarate, and monoethyl itaconate. Among these, from the perspective of ease of synthesis of the (meth)acrylic resin, the residue obtained by removing a hydrogen atom from a carboxy group of (meth)acrylic acid, that is, a (meth)acryloyloxy group is preferable.

Specific examples of the structural unit represented by Formula (3) include structural units represented by the following Formula (3-1).

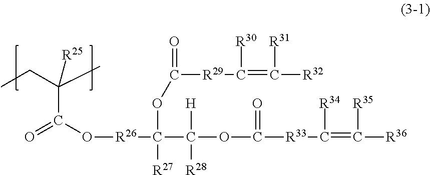

In Formula (3-1), R²⁵ represents a hydrogen atom or a methyl group, R²⁶ represents a divalent linking group, R²⁷, R²⁸, R³⁰, R³¹, R³⁴, and R³⁵ each independently represent a hydrogen atom or an alkyl group having from 1 to 6 carbon atoms, R²⁹ and R³³ each independently represent a single bond or a divalent linking group, and R³² and R³⁶ each independently represent a hydrogen atom, an alkyl group having from 1 to 6 carbon atoms, —COOR (where R represents an alkyl group having from 1 to 6 carbon atoms), or a phenyl group.

In Formula (3-1), specific examples and preferable examples of R²⁶ to R³² are the same as those of R¹⁰ to R¹⁶ in Formula (2-1-1), respectively. In Formula (3-1), specific examples and preferable examples of R³³ to R³⁶ are the same as those of R¹³ to R¹⁶ in Formula (2-1), respectively.

Specific examples of a method for deriving the structural unit represented by Formula (3-1) include a method in which an unsaturated monocarboxylic anhydride is reacted with a hydroxy group of the structural unit represented by Formula (2-1-1) or (2-1-2) described above to introduce a residue obtained by removing a hydrogen atom from a carboxy group of an unsaturated monocarboxylic acid. The unsaturated monocarboxylic anhydride to be reacted may be used singly or in combination of two or more kinds thereof. Examples of the unsaturated monocarboxylic anhydride include (meth)acrylic anhydride.

Specific examples of the structural unit represented by Formula (3) include structural units represented by the following Formula (3-2).

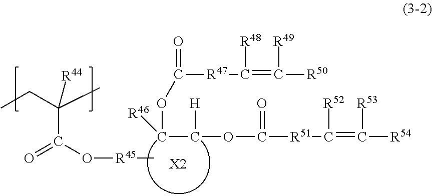

In Formula (3-2), R⁴⁴ represents a hydrogen atom or a methyl group, R⁴⁵ represents a single bond or a divalent linking group, R⁴⁶, R⁴⁸, R⁴⁹, R⁵², and R⁵³ each independently represent a hydrogen atom or an alkyl group having from 1 to 6 carbon atoms, R⁴⁷ and R⁵¹ each independently represent a single bond or a divalent linking group, R⁵⁰ and R⁵⁴ each independently represent a hydrogen atom, an alkyl group having from 1 to 6 carbon atoms, —COOR (where R represents an alkyl group having from 1 to 6 carbon atoms), or a phenyl group, and X2 represents a saturated hydrocarbon ring.

In Formula (3-2), specific examples and preferable examples of R⁴⁵ to R⁵⁰ are the same as those of R³⁸ to R⁴³ in Formula (2-2), respectively. In Formula (3-2), specific examples and preferable examples of R⁵¹ to R⁵⁴ are the same as those of R⁴⁰ to R⁴³ in Formula (2-2), respectively. Specific examples and preferable examples of X2 in Formula (3-2) are the same as those of X1 in Formula (2-2).

Specific examples of a method for deriving the structural unit represented by Formula (3-2) include a method in which an unsaturated monocarboxylic anhydride is reacted with a hydroxy group of the structural unit represented by Formula (2-2) described above to introduce a residue obtained by removing a hydrogen atom from a carboxy group of an unsaturated monocarboxylic acid. The unsaturated monocarboxylic anhydride to be reacted may be used singly or in combination of two or more kinds thereof. Examples of the unsaturated monocarboxylic anhydride include (meth)acrylic anhydride.

The percentage of the structural unit represented by Formula (3), relative to all the structural units of the (meth)acrylic resin (A), is preferably from 0.1 to 30 mol %, more preferably from 0.2 to 28 mol %, and still more preferably from 0.5 to 26 mol %. When the structural unit represented by Formula (3) is 0.1 mol % or more, sufficient improvement in the photocurability can be obtained. As a result, the adhesive strength of the pressure sensitive adhesive composition can be sufficiently reduced at the time of UV irradiation, and the release property from an adherend is improved. When the structural unit represented by Formula (3) is 30 mol % or less, the adhesive strength is good.

### Structural Unit Represented by Formula (4)

The (meth)acrylic resin (A) may contain a structural unit represented by the following Formula (4). The structural unit of the following Formula (4) is preferably contained in a certain amount from the perspective of reducing the residual monomers at the time of synthesis of the (meth)acrylic resin (A), that is, the residual unsaturated monocarboxylic acid and unsaturated monocarboxylic anhydride used for introducing the structural units represented by Formulas (2) and (3) described above. On the other hand, from the perspective of reducing deterioration over time of the pressure sensitive adhesive composition, it is preferable to reduce the content of the structural unit represented by Formula (4) as much as possible.

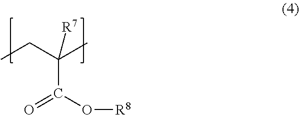

In Formula (4), R⁷ represents a hydrogen atom or a methyl group, and R⁸ represents a group containing an epoxy group. The structural unit represented by Formula (4) does not have to be of one type. R⁷ in each structural unit may be different from one another, and R⁸ in each structural unit may also be different from one another.

Specific examples of the structural unit represented by Formula (4) include structural units represented by the following Formula (4-1) and the following Formula (4-2).

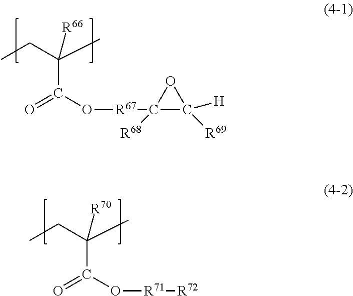

In Formula (4-1), R⁶⁶ represents a hydrogen atom or a methyl group, R⁶⁷ represents a divalent linking group, and R⁶⁸ and R⁶⁹ each independently represent a hydrogen atom or an alkyl group having from 1 to 6 carbon atoms, and in Formula (4-2), R⁷⁰ represents a hydrogen atom or a methyl group, R⁷¹ represents a single bond or a divalent linking group, and R⁷² represents an alicyclic epoxy group.

In Formula (4-1), specific examples and preferable examples of R⁶⁷, R⁶⁸, and R⁶⁹ are the same as those of R¹⁰, R¹¹, and R¹² in Formula (2-1-1), respectively.

Specific examples of the monomers from which the structural unit represented by Formula (4-1) is derived include glycidyl (meth)acrylate and hydroxybutyl (meth)acrylate glycidyl ether. From the perspective of ease of reaction with an unsaturated monocarboxylic acid in deriving the structural units represented by Formulas (2-1-1), (2-1-2), and (3-1), glycidyl (meth)acrylate and hydroxybutyl (meth)acrylate glycidyl ether are preferable.

The monomers from which the structural unit represented by Formula (4-1) is derived may be used singly or in combination of two or more kinds thereof.

Specific examples and preferable examples of R⁷¹ in Formula (4-2) are the same as those of R³⁸ in Formula (2-2).

In Formula (4-2), R⁷² represents an alicyclic epoxy group, and specific examples thereof include a 3,4-epoxycyclohexyl group, an epoxycyclopentyl group, and a 3,4-epoxytricyclo[5.2.1.0^{2, 6}]decanyl group.

Specific examples of the monomers from which the structural unit represented by Formula (4-2) is derived include 3,4-epoxycyclohexylmethyl (meth)acrylate (for example, Cyclomer (trade name) A200 and M100 available from Daicel Corporation), a (meth)acrylic acid ester of a lactone adduct having a 3,4-epoxycyclohexyl group, a mono (meth)acrylic acid ester of 3,4-epoxycyclohexylmethyl-3′,4′-epoxycyclohexanecarboxylate, an epoxidized product of dicyclopentenyl (meth)acrylate, and an epoxidized product of dicyclopentenyloxyethyl (meth)acrylate. Among these, 3,4-epoxycyclohexylmethyl (meth)acrylate is preferable from the perspective of ease of reaction with an unsaturated monocarboxylic acid in deriving the structural units represented by Formulas (2-2) and (3-2). The monomers from which the structural unit represented by Formula (4-2) is derived may be used singly or in combination of two or more kinds thereof.

The percentage of the structural unit represented by Formula (4), relative to all the structural units of the (meth)acrylic resin (A), is preferably from 0 to 10 mol %, more preferably from 0 to 5 mol %, and still more preferably from 0 to 1 mol %. When the structural unit represented by Formula (4) is 10 mol % or less, sufficient heat resistance and storage stability can be obtained, the adhesive strength can be sufficiently reduced after UV irradiation, and an adherend can be released without contamination.

Based on all the structural units of the (meth)acrylic resin (A), the percentage of a total of the structural units represented by Formulas (2) to (4) is preferably 1 mol % or more, more preferably 2 mol % or more, and still more preferably 5 mol % or more. Based on all the structural units of the (meth)acrylic resin (A), the percentage of a total of the structural units represented by Formulas (2) to (4) is preferably 50 mol % or less, more preferably 40 mol % or less, and still more preferably 30 mol % or less. These upper limit values and lower limit values can be freely combined. Based on all the structural units of the (meth)acrylic resin (A), the percentage of a total of the structural units represented by Formulas (2) to (4) is preferably from 1 to 50 mol %, more preferably from 2 to 40 mol %, and still more preferably from 5 to 30 mol %. When the percentage of a total of the structural units represented by Formulas (2) to (4) is 1 mol % or more, sufficient photocurability and desired release property after UV irradiation can be obtained. When the percentage of a total of the structural units represented by Formulas (2) to (4) is 50 mol % or less, pickup properties are good.

The percentage of a total of the structural units represented by Formulas (2) and (3), relative to the total of the structural units represented by Formulas (2) to (4), is preferably 50 mol % or more, more preferably 55 mol % or more, and still more preferably 60 mol % or more. The percentage of a total of the structural units represented by Formulas (2) and (3), relative to the total of the structural units represented by Formulas (2) to (4), is preferably 100 mol % or less, more preferably 95 mol % or less, and still more preferably 90 mol % or less. These upper limit values and lower limit values can be freely combined. The percentage of a total of the structural units represented by Formulas (2) and (3), relative to the total of the structural units represented by Formulas (2) to (4), is preferably from 50 to 100 mol %, more preferably from 55 to 95 mol %, and still more preferably from 60 to 90 mol %. When the percentage of a total of the structural units represented by Formulas (2) and (3) is 50 mol % or more, sufficient photocurability and desired release property after UV irradiation can be obtained.

### Physical Property Value of (Meth)Acrylic Resin (A)

An ethylenically unsaturated group equivalent of the (meth)acrylic resin (A) is preferably 350 g/mol or more, more preferably 400 g/mol or more, and still more preferably 450 g/mol or more. The ethylenically unsaturated group equivalent of the (meth)acrylic resin (A) is preferably 4000 g/mol or less, more preferably 3000 g/mol or less, and still more preferably 2000 g/mol or less. These upper limit values and lower limit values can be freely combined. The ethylenically unsaturated group equivalent of the (meth)acrylic resin (A) is preferably from 350 to 4000 g/mol, more preferably from 400 to 3000 g/mol, and still more preferably from 450 to 2000 g/mol. When the ethylenically unsaturated group equivalent is 350 g/mol or more, the pickup properties are good. When the ethylenically unsaturated group equivalent is 4000 g/mol or less, the adhesiveness before UV irradiation is good.

In the present specification, the ethylenically unsaturated group equivalent of the (meth)acrylic resin is a mass of the (meth)acrylic resin per mole of an ethylenically unsaturated bond (g/mol). The ethylenically unsaturated group equivalent of the (meth)acrylic resin in an embodiment is a calculated value calculated from charged amounts on the assumption that each raw material used in the production of the (meth)acrylic resin is 100% reacted. The ethylenically unsaturated group equivalent of the (meth)acrylic resin may be calculated from an amount of halogen bonded to the (meth)acrylic resin. The amount of halogen bonded to the (meth)acrylic resin can be evaluated in accordance with JIS K 0070:1992.

A glass transition temperature (Tg) of the (meth)acrylic resin (A) is preferably −80° C. or higher, more preferably −70° C. or higher, and still more preferably −65° C. or higher. The glass transition temperature (Tg) of the (meth)acrylic resin (A) is preferably 0° C. or lower, more preferably −10° C. or lower, and still more preferably −20° C. or lower. These upper limit values and lower limit values can be freely combined. A glass transition temperature (Tg) of the (meth)acrylic resin (A) is preferably from −80° C. to 0° C., more preferably from −70° C. to −10° C., and still more preferably from −65° C. to −20° C. When the glass transition temperature is −80° C. or higher, the pickup properties are good. When the glass transition temperature is 0° C. or lower, the adhesiveness before UV irradiation is good.

In the present specification, the “glass transition temperature (Tg)” is a temperature at which heat absorption starts due to glass transition observed when 10 mg of a sample is taken and subjected to differential scanning calorimetry using a differential scanning calorimeter (DSC) while changing the temperature of the sample from −100° C. to 200° C. at a rate of temperature increase of 10° C./min. If two or more heat absorption start temperatures are observed, the Tg is a simple average of the two or more heat absorption start temperatures.

A weight average molecular weight of the (meth)acrylic resin (A) is preferably 100000 or more, more preferably 200000 or more, and still more preferably 300000 or more. The weight average molecular weight of the (meth)acrylic resin (A) is preferably 1000000 or less, more preferably 900000 or less, and still more preferably 800000 or less. These upper limit values and lower limit values can be freely combined. The weight average molecular weight of the (meth)acrylic resin (A) is preferably from 100000 to 1000000, more preferably from 200000 to 900000, and still more preferably from 300000 to 800000. When the weight average molecular weight is 100000 or more, cohesiveness before UV irradiation is good. When the weight average molecular weight is 1000000 or less, handleability at the time of coating is good.

In the present specification, the “weight-average molecular weight (Mw)” is a value measured using gel permeation chromatography (GPC) at normal temperature (23° C.) under the following conditions, and determined using a standard polystyrene calibration curve.

Apparatus: Shodex (trademark) GPC-101 (Showa Denko K.K.)

Column: Shodex (trademark) LF-804 (Showa Denko K.K.)

Column temperature: 40° C.

Sample: 0.2% by mass solution of a sample in tetrahydrofuran

Flow rate: 1 mL/min

Eluent: tetrahydrofuran

Detector: Shodex (trademark) RI-71S (Showa Denko K.K.)

A hydroxyl value of the (meth)acrylic resin (A) is preferably 1 mgKOH/g or more, more preferably 2 mgKOH/g or more, and still more preferably 3 mgKOH/g or more. The hydroxyl value of the (meth)acrylic resin (A) is preferably 60 mgKOH/g or less, more preferably 50 mgKOH/g or less, and still more preferably 40 mgKOH/g or less. These upper limit values and lower limit values can be freely combined. The hydroxyl value of the (meth)acrylic resin (A) is preferably from 1 to 60 mgKOH/g, more preferably from 2 to 50 mgKOH/g, and still more preferably from 3 to 40 mgKOH/g. When the hydroxyl value is 1 mgKOH/g or more, a desired cohesive strength can be obtained upon reaction with the crosslinking agent (C). When the hydroxyl value is 60 mgKOH/g or less, the release property after UV irradiation is good.

In the present specification, the hydroxyl value is a mass (mg) of potassium hydroxide required to neutralize acetic acid bonded to a hydroxyl group when 1 g of a resin is acetylated in accordance with JIS K 0070:1992.

### Method for Producing (Meth)Acrylic Resin (A)

The (meth)acrylic resin (A) can be obtained by, for example, a step (i) of polymerizing a monomer having an epoxy group and another monomer to obtain a copolymer, a step (ii) of adding an unsaturated monocarboxylic acid to the epoxy group of the copolymer, and a step (iii) of adding an unsaturated monocarboxylic anhydride to a hydroxy group generated by ring-opening of an epoxy group in an addition reaction in the step (ii), and simultaneously adding a free unsaturated monocarboxylic acid derived from the unsaturated monocarboxylic anhydride to a remaining epoxy group.

### Step (i) of Polymerizing Monomer to Obtain Copolymer

Examples of polymerization method that can be used include a solution polymerization method, an emulsion polymerization method, a bulk polymerization method, a suspension polymerization method, and an alternating copolymerization method. Among these polymerization methods, in consideration of the addition reaction in steps (ii) and (iii), a solution polymerization method is preferably used in terms of ease of reaction.

As the monomers, an alkyl (meth)acrylate, an epoxy group-containing (meth)acrylate, and optionally other monomers can be used.

### Alkyl (Meth)Acrylate

The alkyl (meth)acrylate is not particularly limited as long as it is a monomer from which the structural unit represented by Formula (1) is derived. Specific examples thereof include methyl (meth)acrylate, ethyl (meth)acrylate, butyl (meth)acrylate, hexyl (meth)acrylate, 2-ethylhexyl (meth)acrylate, and decyl (meth)acrylate. Among these, from the perspective of ease of synthesis of the (meth)acrylic resin (A) and the adhesive property as well as the release property after UV irradiation, methyl (meth)acrylate, ethyl (meth)acrylate, butyl (meth)acrylate, and 2-ethylhexyl (meth)acrylate are preferable, and from the perspective of release property after UV irradiation, 2-ethylhexyl (meth)acrylate is more preferable. The alkyl (meth)acrylate may be used singly or in combination of two or more kinds thereof.

### Epoxy Group-Containing (Meth)Acrylate

The epoxy group-containing (meth)acrylate is not particularly limited as long as it is a monomer from which the structural unit represented by Formula (4) is derived. Specific examples thereof include glycidyl (meth)acrylate, hydroxybutyl (meth)acrylate glycidyl ether, 3,4-epoxycyclohexylmethyl (meth)acrylate (for example, Cyclomer (trade name) A200 and M100 available from Daicel Corporation), a (meth)acrylic acid ester of a lactone adduct having a 3,4-epoxycyclohexyl group, a mono (meth)acrylic acid ester of 3,4-epoxycyclohexylmethyl-3′,4′-epoxycyclohexanecarboxylate, an epoxidized product of dicyclopentenyl (meth)acrylate, and an epoxidized product of dicyclopentenyloxyethyl (meth)acrylate. Among these, glycidyl (meth)acrylate, 3,4-epoxycyclohexylmethyl (meth)acrylate, and hydroxybutyl (meth)acrylate glycidyl ether are preferable from the perspective of ease of reaction with an unsaturated monocarboxylic acid. The epoxy group-containing (meth)acrylate may be used singly or in combination of two or more kinds thereof.

### Other Monomers

Other monomers are not particularly limited as long as they are monomers not having a carboxy group, and they derive structural units other than the structural units represented by Formulas (1) to (4) and are copolymerizable with the alkyl (meth)acrylate and the epoxy group-containing (meth)acrylate described above. Specific examples thereof include alicyclic ring-containing (meth)acrylates, aromatic ring-containing (meth)acrylates, hydroxy group-containing (meth)acrylates, and amide group-containing (meth)acrylates.

Examples of the alicyclic ring-containing (meth)acrylates include cyclohexyl (meth)acrylate, methylcyclohexyl (meth)acrylate, norbornyl (meth)acrylate, 5-ethylnorbomyl (meth)acrylate, isobornyl (meth)acrylate, and adamantyl (meth)acrylate.

Examples of the aromatic ring-containing (meth)acrylates include benzyl (meth)acrylate, triphenylmethyl (meth)acrylate, phenyl (meth)acrylate, cumyl (meth)acrylate, 4-phenoxyphenyl (meth)acrylate, phenoxyethyl (meth)acrylate, phenoxypolyethylene glycol (meth)acrylate, nonylphenoxypolyethylene glycol mono (meth)acrylate, biphenyloxyethyl (meth)acrylate, naphthalene (meth)acrylate, and anthracene (meth)acrylate.

Examples of the hydroxy group-containing (meth)acrylates include 2-hydroxyethyl (meth)acrylate, 2-hydroxypropyl (meth)acrylate, 2-hydroxybutyl (meth)acrylate, 2,3-dihydroxypropyl (meth)acrylate, 4-hydroxybutyl (meth)acrylate, and 2-hydroxy-3-phenoxypropyl (meth)acrylate.

Examples of the amide group-containing (meth)acrylates include (meth)acrylamide, N,N-dimethyl (meth)acrylamide, N,N-diisopropyl (meth)acrylamide, and anthracenyl (meth)acrylamide.

The alkyl (meth)acrylate content in the total monomers is preferably from 50 to 99 mol %, more preferably from 60 to 98 mol %, and still more preferably from 70 to 95 mol %.

The epoxy group-containing (meth)acrylate content in the total monomers is preferably from 1 to 50 mol %, more preferably from 2 to 40 mol %, and still more preferably from 5 to 30 mol %.

### Radical Polymerization Initiator

The polymerization is preferably carried out in the presence of a radical polymerization initiator. Examples of the radical polymerization initiators include common organic radical polymerization initiators, and specific examples thereof include oil-soluble polymerization initiators such as azo-based polymerization initiators including 2,2′-azobis(isobutyronitrile), 2,2′-azobis(4-methoxy-2,4-dimethylvaleronitrile), 2,2′-azobis(2,4-dimethylvaleronitrile), 2,2′-azobis(2-methylbutyronitrile), 1,1′-azobis(cyclohexane-1-carbonitrile), 2,2′-azobis(2,4,4-trimethylpentane), and dimethyl-2,2′-azobis(2-methylpropionate); and peroxide-based polymerization initiators including benzoyl peroxide, t-butyl hydroperoxide, di-t-butyl peroxide, t-butyl peroxybenzoate, dicumyl peroxide, 1,1-bis(t-butylperoxy)-3,3,5-trimethylcyclohexane, and 1,1-bis(t-butylperoxy)cyclododecane.

The radical polymerization initiators may be used singly, or two or more types thereof may be used in combination.

The amount of the radical polymerization initiator used is preferably from 0.001 to 5 parts by mass, more preferably from 0.005 to 3 parts by mass, and still more preferably from 0.01 to 1 parts by mass, per 100 parts by mass of the total amount of monomers.

### Solvent

As a solvent used for solution polymerization, a common solvent can be used. Examples of the solvents include esters such as ethyl acetate, propyl acetate, and butyl acetate; aromatic hydrocarbons such as toluene, xylene, and benzene; aliphatic hydrocarbons such as hexane and heptane; cycloaliphatic hydrocarbons such as cyclohexane and methylcyclohexane; ketones such as methyl ethyl ketone and methyl isobutyl ketone; glycols such as ethylene glycol, propylene glycol, and dipropylene glycol; glycol ethers such as methyl cellosolve, propylene glycol monomethyl ether, and dipropylene glycol monomethyl ether; and glycol esters such as ethylene glycol diacetate and propylene glycol monomethyl ether acetate. The solvents may be used singly, or two or more types thereof may be used in combination.

### Reaction Conditions

The polymerization reaction temperature is usually from 30° C. to 130° C., preferably from 40° C. to 120° C., and more preferably 50° C. to 110° C., depending on the type of radical polymerization initiator used. When the temperature during polymerization is 30° C. or higher, an adequate reaction rate can be obtained. When the temperature during polymerization is 130° C. or lower, there is little risk during production.

The polymerization reaction time is usually from 3 hours to 30 hours, preferably from 4 hours to 20 hours, and more preferably from 5 hours to 15 hours, depending on the type of a monomer and a radical polymerization initiator to be used. When the reaction time is 3 hours or more, a copolymer can be produced from the monomer at a suitable polymerization degree, and when the reaction time is 30 hours or less, the production can be efficiently carried out.

Step (ii) of adding unsaturated monocarboxylic acid to epoxy group of copolymer, and step (iii) of adding unsaturated monocarboxylic anhydride to copolymer Steps (ii) and (iii) may be performed in this order or performed simultaneously. From the perspective of simplicity of the operation, it is preferable to simultaneously perform the steps (ii) and (iii).

### Unsaturated Monocarboxylic Acid

The unsaturated monocarboxylic acid is not particularly limited as long as it is a monocarboxylic acid having an ethylenically unsaturated group. Specific examples thereof include (meth)acrylic acid, 2-(meth)acryloyloxyethylsuccinic acid, 2-(meth)acryloyloxyethylhexahydrophthalic acid, crotonic acid, propiolic acid, cinnamic acid, monomethyl maleate, monoethyl maleate, monoisopropyl maleate, monomethyl fumarate, and monoethyl itaconate. Among these, (meth)acrylic acid is preferable from the perspective of ease of synthesis of the (meth)acrylic resin (A). The unsaturated monocarboxylic acid may be used singly or in combination of two or more kinds thereof.

### Unsaturated Monocarboxylic Anhydride

The unsaturated monocarboxylic anhydride is not particularly limited as long as it is a monocarboxylic anhydride having an ethylenically unsaturated group. Specific examples thereof include (meth)acrylic anhydride. The unsaturated monocarboxylic anhydride may be used singly or in combination of two or more kinds thereof.

The addition ratio of the unsaturated monocarboxylic acid to the epoxy group derived from the epoxy group-containing (meth)acrylate present in the copolymer is preferably 50% or more, more preferably 60% or more, and still more preferably 70% or more. When the addition ratio is 50% or more, good release property can be obtained after UV irradiation. The addition ratio is preferably as high as possible from the perspective of heat resistance, and in one aspect, the addition ratio of the unsaturated monocarboxylic acid to the epoxy group derived from the epoxy group-containing (meth)acrylate present in the copolymer is 100%. The upper limit of the addition ratio may be, for example, 99% or 98%. The addition ratio of the unsaturated monocarboxylic acid to the epoxy group derived from the epoxy group-containing (meth)acrylate present in the copolymer is calculated from the charged amount.

With respect to a ratio between the unsaturated monocarboxylic acid and the unsaturated monocarboxylic anhydride, the unsaturated monocarboxylic acid is preferably from 5 to 130 mol, more preferably from 10 to 120 mol, and still more preferably from 15 to 110 mol, per 100 mol of the unsaturated monocarboxylic anhydride. When the unsaturated monocarboxylic acid is 130 mol or less, per 100 mol of the unsaturated monocarboxylic anhydride, the adhesiveness to an adherend is improved. When the unsaturated monocarboxylic acid is 5 mol or more, per 100 mol of the unsaturated monocarboxylic anhydride, the release property after UV irradiation is improved.

### Catalyst

In the addition reaction in steps (ii) and (iii), a known catalyst can be used as necessary. As the catalyst, a known catalyst can be used, and is not particularly limited. Examples thereof include triphenylphosphine, tri(p-tolyl)phosphine, and tris(2,6-dimethoxyphenyl)phosphine. The catalysts may be used singly, or two or more types thereof may be used in combination.

When a catalyst is used, the amount of the catalyst used is preferably from 2.5 to 10 mol, more preferably from 3.0 to 9.0 mol, and still more preferably from 3.5 to 8.0 mol, per 100 mol of the epoxy group-containing (meth)acrylate used for producing the copolymer. When the amount of the catalyst used is 2.5 mol or more, the addition reaction can be promoted. On the other hand, when the amount of the catalyst used is 10 mol or less, gelation during the addition reaction can be suppressed.

### Polymerization Inhibitor

In the addition reaction in steps (ii) and (iii), a known polymerization inhibitor can be used, as necessary. As the polymerization inhibitor, a known polymerization inhibitor can be used, and is not particularly limited. Examples thereof include 4-methoxyphenol, hydroquinone, methoquinone, 2,6-di-t-butylphenol, 2,2′-methylenebis(4-methyl-6-t-butylphenol), and phenothiazine. The polymerization inhibitors may be used singly, or two or more types thereof may be used in combination.

When a polymerization inhibitor is used, the amount of the polymerization inhibitor used is preferably from 0.005 to 5 parts by mass, more preferably from 0.03 to 3 parts by mass, and still more preferably from 0.05 to 1.5 parts by mass, per 100 parts by mass of the copolymer. When the amount of the polymerization inhibitor used is 0.005 parts by mass or more, gelation during the addition reaction can be prevented. On the other hand, when the amount of the polymerization inhibitor used is 5 parts by mass or less, an adequate exposure sensitivity of the (meth)acrylic resin (A) upon UV irradiation can be obtained.

### Solvent

As a solvent, a common solvent can be used. As the solvent, for example, the same solvent as the one used in the solution polymerization in step (i) can be used. Toluene in which a chain transfer reaction easily occurs, or an alcohol such as 1-methoxy-2-propanol may be used. The solvents may be used singly, or two or more types thereof may be used in combination.

### Reaction Conditions

A temperature of the addition reaction is preferably from 25° C. to 130° C., and particularly preferably from 40° C. to 120° C. When the temperature of the addition reaction is 25° C. or higher, an adequate reaction speed can be obtained. When the temperature of the addition reaction is 130° C. or lower, the occurrence of a gelled product due to crosslinked double bond portion through radical polymerization by heat can be prevented. The time for the addition reaction is preferably from 2 to 24 hours, and more preferably from 2 to 12 hours.

Furthermore, at the time of the addition reaction, a gas effective to inhibit polymerization may be introduced into the reaction system. When a gas effective to inhibit polymerization is introduced into the reaction system, gelation during the addition reaction can be prevented.

As the gas effective to inhibit polymerization, mention may be made of a gas that contains oxygen to the extent that does not fall within the explosion range of the substance in the system, and examples thereof include air.

Combined use of a gas effective to inhibit a polymerization and a polymerization inhibitor is more preferable because the amount of the polymerization inhibitor to be used can be reduced or the effect to inhibit polymerization can be enhanced.

### Photopolymerization Initiator (B)

Examples of the photopolymerization initiator (B) include carbonyl-based photopolymerization initiators, such as benzophenone, benzyl, benzoin, ω-bromoacetophenone, chloroacetone, acetophenone, 2,2-diethoxyacetophenone, 2,2-dimethoxy-2-phenylacetophenone, p-dimethylaminoacetophenone, p-dimethylaminopropiophenone, 2-chlorobenzophenone, 4,4′-dichlorobenzophenone, 4,4′-bisdiethylaminobenzophenone, Michler's ketone, benzoin methyl ether, benzoin isobutyl ether, benzoin-n-butyl ether, benzyl methyl ketal, 1-hydroxycyclohexyl phenyl ketone, 2-hydroxy-2-methyl-1-phenyl-propane-1-one, 1-(4-isopropylphenyl)-2-hydroxy-2-methylpropane-1-one, methyl benzoylformate, 4′-dimethylaminoacetophenone, and 2-methyl-1-[4-(methylthio)phenyl]-2-morpholinopropane-1-one.

Examples of the photopolymerization initiator (B) also include sulfide-based photopolymerization initiators, such as diphenyl disulfide, dibenzyl disulfide, tetraethylthiuram disulfide, and tetramethylammonium monosulfide; acylphosphine oxides, such as 2,4,6-trimethylbenzoyldiphenylphosphine oxide and 2,4,6-trimethylbenzoylphenylethoxyphosphine oxide; quinone-based photopolymerization initiators, such as benzoquinone and anthraquinone; sulfochloride-based photopolymerization initiators; and thioxanthone-based photopolymerization initiators, such as thioxanthone, 2-chlorothioxanthone, and 2-methylthioxanthone.

Among these photopolymerization initiators (B), from the perspective of solubility in the pressure-sensitive adhesive composition, carbonyl-based photopolymerization initiators and acylphosphine oxides are preferable, and at least one selected from 1-hydroxycyclohexyl phenyl ketone and 2,4,6-trimethylbenzoyldiphenylphosphine oxide is more preferably used.

The photopolymerization initiator (B) may be used singly or in combination of two or more kinds thereof.

The photopolymerization initiator (B) content is preferably from 0.1 to 5.0 parts by mass, and more preferably from 0.5 to 2.0 parts by mass, per 100 parts by mass of the (meth)acrylic resin (A). When the photopolymerization initiator (B) content per 100 parts by mass of the (meth)acrylic resin (A) is 0.1 parts by mass or more, the pressure sensitive adhesive composition can be cured at a sufficiently high curing rate during UV irradiation, so that the adhesive strength of the ultraviolet curable pressure sensitive adhesive layer after UV irradiation can be sufficiently reduced. When the photopolymerization initiator (B) content per 100 parts by mass of the (meth)acrylic resin (A) is 5.0 parts by mass or less, the pressure sensitive adhesive layer hardly remains on an adherend when the pressure sensitive adhesive sheet including the ultraviolet curable pressure sensitive adhesive layer, which is a thermally cured product of the pressure sensitive adhesive composition, is released after being bonded to the adherend. When the pressure sensitive adhesive composition is used as a pressure sensitive adhesive layer of a dicing/die-bonding integrated film, the release property from an adhesive layer after UV irradiation and the pickup properties are good. An effect commensurate with the content of the photopolymerization initiator (B) is not exhibited when the photopolymerization initiator (B) content per 100 parts by mass of the (meth)acrylic resin (A) is more than 5.0 parts by mass, and therefore the content is adjusted to 5.0 parts by mass or less, so that a pressure sensitive adhesive composition can be produced economically.

### Crosslinking Agent (C)

The crosslinking agent (C) is a compound having no ethylenically unsaturated bond and having two or more functional groups reactive with the hydroxy group contained in the (meth)acrylic resin (A). The crosslinking agent (C) provides a good balance between the adhesive strength before UV irradiation and the adhesive strength after UV irradiation.

Examples of the functional group having reactivity with the hydroxy group include an isocyanato group, an epoxy group, a carboxy group, an acid anhydride group, and an aziridinyl group. From the perspective of reactivity, an isocyanato group and an epoxy group are preferable, and an isocyanato group is particularly preferable.

Examples of the crosslinking agent (C) include polyisocyanates such as 2,4-tolylene diisocyanate, 2,6-tolylene diisocyanate, hydrogenated tolylene diisocyanate, 1,3-xylylene diisocyanate, 1,4-xylylene diisocyanate, diphenylmethane-4,4′-diisocyanate, isophorone diisocyanate, 1,3-bis(isocyanatomethyl)cyclohexane, isocyanurate forms of hexamethylene diisocyanate, tetramethylxylylene diisocyanate, 1,5-naphthalene diisocyanate, tolylene diisocyanate adducts of trimethylolpropane, xylylene diisocyanate adducts of trimethylolpropane, triphenylmethane triisocyanate and methylenebis(4-phenylmethane)triisocyanate; polyepoxy compounds such as 1,3-bis(N,N′-diglycidylaminomethyl)cyclohexane, bisphenol A-epichlorohydrin type epoxy resin, N,N′-[1,3-phenylenebis(methylene)]bis[bis(oxirane-2-ylmethyl)amine], ethylene glycol diglycidyl ether, polyethylene glycol diglycidyl ether, glycerin diglycidyl ether, glycerin triglycidyl ether, 1,6-hexanediol diglycidyl ether, trimethylolpropane triglycidyl ether, sorbitol polyglycidyl ether, polyglycerol polyglycidyl ether, pentaerythritol polyglycidyl ether, and diglycerol polyglycidyl ether; aziridine compounds such as tetramethylolmethane-tri-o-aziridinyl propionate, trimethylolpropane-tri-o-aziridinyl propionate, N,N′-diphenylmethane-4,4′-bis (1-aziridinecarboxamide), N,N′-hexamethylene-1,6-bis(1-aziridinecarboxamide), ethylene glycol-bis-[3-(2-aziridinyl)propionate], trimethylolpropane-tris [3-(2-aziridinyl)propionate], trimethylolpropane-tris [3-(1-aziridinyl)propionate], trimethylolpropane-tris [3-(2-methyl-1-aziridinyl)propionate], tetramethylolmethane-tris [3-(2-aziridinyl)propionate], and pentaerythritol-tris [3-(1-aziridinyl)propionate]; and melamine compounds such as hexamethoxymethylmelamine, hexaethoxymethylmelamine, hexapropoxymethylmelamine, hexabutoxymethylmelamine, hexapentyloxymethylmelamine and hexahexyloxymethylmelamine.

Among these crosslinking agents (C), it is preferable to use at least one selected from the group consisting of polyisocyanates and polyepoxy compounds, and it is more preferable to use polyisocyanates, because they have good reactivity with the (meth)acrylic resin (A).

The crosslinking agent (C) may be used singly or in combination of two or more kinds thereof.

The crosslinking agent (C) content is preferably from 0.1 to 30 parts by mass, more preferably from 0.1 to 20 parts by mass, still more preferably from 0.1 to 10 parts by mass, and even more preferably from 0.1 to 5 parts by mass, per 100 parts by mass of the (meth)acrylic resin (A). When the crosslinking agent (C) content per 100 parts by mass of the (meth)acrylic resin (A) is 0.1 parts by mass or more, a crosslinked structure with the (meth)acrylic resin (A) is sufficiently formed during heating, so that strength of the ultraviolet curable pressure sensitive adhesive layer before UV irradiation is good. When the crosslinking agent (C) content per 100 parts by mass of the (meth)acrylic resin (A) is 30 parts by mass or less, the adhesive strength of the pressure sensitive adhesive composition before UV irradiation is good.

### Additional Component

The pressure sensitive adhesive composition may contain an additional component other than the (meth)acrylic resin (A), the photopolymerization initiator (B), and the crosslinking agent (C) described above, as necessary. Examples of the additional component include a tackifier, a solvent, and various additives.

### Tackifier

As the tackifier, a known tackifier can be used without particular limitation. Examples of the tackifier include a terpene-based tackifier resin, a phenol-based tackifier resin, a rosin-based tackifier resin, an aliphatic petroleum resin, an aromatic petroleum resin, a copolymer petroleum resin, an alicyclic petroleum resin, a xylene resin, an epoxy-based tackifier resin, a polyamide-based tackifier resin, a ketone-based tackifier resin, and an elastomer-based tackifier resin. The tackifier may be used singly or in combination of two or more kinds thereof.

When the tackifier is mixed, an addition amount thereof is preferably 30 parts by mass or less, and more preferably from 5 to 20 parts by mass, per 100 parts by mass of the (meth)acrylic resin (A).

### Solvent

The solvent can be used to dilute the pressure-sensitive adhesive composition for the purpose of adjusting the viscosity of the pressure-sensitive adhesive composition. For example, when the pressure-sensitive adhesive composition is applied, a solvent can be used to adjust the viscosity of the pressure-sensitive adhesive composition to an appropriate viscosity. As the solvent, the solvent used when synthesizing the (meth)acrylic resin (A) may be used as it is, or a solvent may be further added to the solvent.

Examples of the solvent that can be used include organic solvents, such as methyl ethyl ketone, methyl isobutyl ketone, acetone, ethyl acetate, propyl acetate, tetrahydrofuran, dioxane, cyclohexanone, hexane, toluene, xylene, n-propanol, and isopropyl alcohol. The solvent may be used singly or in combination of two or more kinds thereof.

### Additives

Examples of the additives include plasticizers, surface lubricants, leveling agents, softeners, antioxidants, antiaging agents, light stabilizers, such as a benzotriazole-based compound, ultraviolet absorbers, polymerization inhibitors, phosphoric acid ester-based and other flame retardants, surfactants, and antistatic agents.

### Ultraviolet Curable Pressure Sensitive Adhesive Layer

The ultraviolet curable pressure sensitive adhesive layer is a thermally cured product of the pressure sensitive adhesive composition. The conditions for thermal curing are not particularly limited, and the pressure sensitive adhesive composition is usually applied, and then thermally cured by heat-drying and/or curing. The conditions for heat-drying are usually at a temperature ranging from 25 to 180° C., preferably from 60 to 150° C., and usually for a period of time ranging from 1 to 20 minutes, preferably from 1 to 10 minutes. When the pressure sensitive adhesive composition contains a solvent, the solvent can be removed by the heat-drying within the abovementioned ranges. The conditions for curing the heat-dried sheet in an oven for a certain period of time are not particularly limited, and are usually at a temperature ranging from 25 to 100° C., preferably from 30 to 80° C., and usually for a period of time ranging from 1 to 30 days, preferably from 1 to 14 days. When the curing is carried out under the above-described conditions, the (meth)acrylic resin (A) can be crosslinked with the crosslinking agent (C), whereby a gel fraction of the pressure sensitive adhesive layer can be adjusted to be within a desired range.

The thickness of the ultraviolet curable pressure sensitive adhesive layer can be appropriately adjusted according to the application.

### Pressure Sensitive Adhesive Sheet

The pressure sensitive adhesive sheet includes an ultraviolet curable pressure sensitive adhesive layer and a substrate layer.

### Substrate Layer

As the substrate layer, for example, a known inorganic substrate, a polymer sheet, and a polymer film can be used, and there is no particular limitation. Specific examples thereof include polyolefins such as crystalline polypropylene, amorphous polypropylene, high-density polyethylene, medium-density polyethylene, low-density polyethylene, very low density polyethylene, low-density linear polyethylene, polybutene, and polymethylpentene, ethylene-vinyl acetate copolymers, ionomer resins, ethylene-(meth)acrylic acid copolymers, ethylene-(meth)acrylic acid ester (random, alternating) copolymers, ethylene-butene copolymers, ethylene-hexene copolymers, polyurethane, polyesters such as polyethylene terephthalate and polyethylene naphthalate, polycarbonate, polyimide, polyetheretherketone, polyimide, polyetherimide, polyamide, wholly aromatic polyamide, polyphenylsulfide, aramid (paper), glass, glass cloth, fluororesin, polyvinyl chloride, polyvinylidene chloride, cellulose-based resin, silicone resin, mixtures thereof with a plasticizer, and cured products thereof crosslinked by electron beam irradiation.

When the pressure sensitive adhesive composition is used for a dicing/die-bonding integrated film, the substrate layer is preferably one that can be subjected to an expanding step under low temperature conditions, and has a surface mainly composed of at least one resin selected from polyethylene, polypropylene, a polyethylene-polypropylene random copolymer, and a polyethylene-polypropylene block copolymer, and the pressure sensitive adhesive layer is preferably in contact with the surface. These resins are good substrates from the perspective of properties such as Young's modulus, stress relaxation, and melting point, costs, and recycling of waste materials after use. The substrate layer may be a single layer, and may have a multilayer structure in which layers formed of different materials are stacked, as necessary. In order to control adhesiveness to the pressure sensitive adhesive layer, the surface of the substrate layer may be subjected to a surface roughening treatment such as a mat treatment or a corona treatment.

### Method for Producing Pressure Sensitive Adhesive Sheet

The pressure sensitive adhesive sheet can be produced, for example, by the following method.

First, a pressure sensitive adhesive solution in which a pressure sensitive adhesive composition is dissolved or dispersed in a solvent is prepared. The pressure sensitive adhesive composition may be used as it is for the pressure sensitive adhesive solution.

Next, the pressure sensitive adhesive solution is applied onto a substrate, and when the pressure sensitive adhesive solution contains a solvent, the solvent is removed by heat-drying, to form a pressure sensitive adhesive layer. Thereafter, a release sheet is bonded onto the pressure sensitive adhesive layer, as necessary. Further, if necessary, the obtained sheet is cured in an oven for a certain period of time to form a crosslinked structure, whereby a pressure sensitive adhesive sheet can be obtained.

The pressure sensitive adhesive sheet can also be produced by the following method. A pressure sensitive adhesive solution is applied onto a release sheet, and when a solvent is contained, the solvent is removed by heat-drying, to form a pressure sensitive adhesive layer. Thereafter, the release sheet having the pressure sensitive adhesive layer thereon is placed on the substrate so the surface on the side of the pressure sensitive adhesive layer as to face the substrate, and the pressure sensitive adhesive layer is transferred onto (migrates to) the substrate. Further, if necessary, the obtained sheet is cured in an oven for a certain period of time to form a crosslinked structure, whereby a pressure sensitive adhesive sheet can be obtained.

In the above-described method, a dicing/die-bonding integrated film can be obtained by applying a pressure sensitive adhesive composition to an adhesive layer using a substrate having the adhesive layer as a substrate or stacking an adhesive layer and a pressure sensitive adhesive layer so that the adhesive layer and the pressure sensitive adhesive layer face each other. By applying the adhesive composition to the pressure sensitive adhesive layer having the crosslinked structure formed by the above-described method, a dicing/die-bonding integrated film can also be obtained.

As a method for applying the pressure sensitive adhesive solution onto the substrate (or onto the release sheet), a known method can be used. Specific examples of the method include a method in which coating is performed with a common use coater such as a gravure roll coater, a reverse roll coater, a kiss roll coater, a dip roll coater, a bar coater, a knife coater, a spray coater, a comma coater, or a direct coater.

The conditions for heat-drying the applied pressure sensitive adhesive solution are not particularly limited, but the heat-drying are carried out usually at a temperature from 25 to 180° C., and preferably from 60 to 150° C., and usually for a period of time from 1 to 20 minutes, and preferably from 1 to 10 minutes. When the heat-drying is carried out within the above-mentioned range, the solvent contained in the pressure sensitive adhesive solution can be removed. The conditions for curing the heat-dried sheet in an oven for a certain period of time are not particularly limited, but curing is carried out usually at a temperature ranging from 25 to 100° C., preferably from 30 to 80° C., and usually for a period of time ranging from 1 to 30 days, preferably from 1 to 14 days. When the curing is carried out under the above-described conditions, the (meth)acrylic resin (A) can be crosslinked with the crosslinking agent (C), whereby a gel fraction of the pressure sensitive adhesive layer can be adjusted to be within a desired range.

### Use of Pressure Sensitive Adhesive Sheet

The pressure sensitive adhesive sheet can be used as a removable pressure sensitive adhesive sheet, for example, when an electronic component is produced. Specifically, the removable pressure sensitive adhesive sheet is used for a purpose of fixing an adherend in each step of producing an electronic component, subjecting the adherend to various processing steps, and then peeling off the adherend by irradiation with UV (ultraviolet rays). Therefore, the pressure sensitive adhesive sheet can be used as a back grinding tape, a dicing tape, or the equivalent thereof in processing a semiconductor wafer. The pressure sensitive adhesive sheet can also be used as a supporting tape for a fragile member such as an ultrathin glass substrate and a member that is easily warped such as an FPC substrate. In particular, the pressure sensitive adhesive sheet has excellent pressure sensitive adhesiveness to an adhesive layer and excellent release property after UV irradiation, and thus is suitable for a dicing tape used in the production of a dicing/die-bonding integrated film.

When the pressure sensitive adhesive sheet is used as a dicing tape of a wafer, before performing a dicing step, the pressure sensitive adhesive sheet is attached to a wafer on which a plurality of components are formed. Next, the wafer is cut (diced) into individual components to obtain small element pieces (chips). Thereafter, the pressure sensitive adhesive sheet attached on each element piece is irradiated with UV. The ultraviolet curable pressure sensitive adhesive layer is irradiated with UV through the substrate of the pressure sensitive adhesive sheet, and as curing occurs, the unsaturated bonds in the pressure sensitive adhesive layer form a three dimensional crosslinked structure. As a result, the adhesive strength of the pressure sensitive adhesive layer is reduced. Thereafter, the pressure sensitive adhesive sheet is released from each element piece.

Examples of the light source used when UV irradiation is performed include a high-pressure mercury lamp, an ultra-high pressure mercury lamp, a carbon arc lamp, a xenon lamp, a metal halide lamp, a chemical lamp, and a black light.

An irradiation amount of UV with which the pressure sensitive adhesive sheet is irradiated is preferably from 50 to 3000 mJ/cm², and more preferably from 100 to 600 mJ/cm². When the irradiation amount of UV with which the pressure sensitive adhesive sheet is irradiated is 50 mJ/cm² or more, the ultraviolet curable pressure sensitive adhesive layer can be cured at a sufficiently high curing rate by UV irradiation, and hence the adhesive strength of the pressure sensitive adhesive layer after the UV irradiation can be sufficiently reduced. Even when the irradiation amount of UV with which the pressure sensitive adhesive sheet is irradiated exceeds 3000 mJ/cm², an effect commensurate with the UV irradiation amount is not obtained; therefore, by setting the UV irradiation amount with which the pressure sensitive adhesive sheet is irradiated to 3000 mJ/cm² or less, the pressure sensitive adhesive sheet can be economically released while reducing the influence of UV irradiation on an adherend.

### EXAMPLES

Hereinafter, the present invention will be described more specifically with reference to Examples and Comparative Examples, but the present invention is not limited to the following Examples.

The raw materials used in the synthesis of the (meth)acrylic resins (A) and (cA) are indicated.
Methyl acrylate, Nippon Shokubai Co., Ltd.,
n-butyl acrylate, OSAKA ORGANIC CHEMICAL INDUSTRY LTD.,
2-ethylhexyl acrylate, OSAKA ORGANIC CHEMICAL INDUSTRY LTD.,
Glycidyl methacrylate, NOF CORPORATION,
4-hydroxybutyl acrylate glycidyl ether, Mitsubishi Chemical Corporation,
3,4-epoxycyclohexylmethyl methacrylate, Daicel Corporation,
3,4-epoxytricyclo[5.2.1.0^{2, 6}]decaneoxyethyl acrylate,
Acrylic acid, Nippon Shokubai Co., Ltd.,
2-hydroxyethyl acrylate, Nippon Shokubai Co., Ltd.,
Methacrylic acid, Nippon Shokubai Co., Ltd.,
Methacrylic anhydride, Evonik Japan Co., Ltd.,
Karenz (trade name) MOI, 2-isocyanatoethyl methacrylate, Showa Denko K.K.,

### Radical Polymerization Initiator:

2,2′-azobis (isobutyronitrile), FUJIFILM Wako Pure Chemical Corporation

### Catalyst:

Triphenylphosphine, Hokko Chemical Industry Co., Ltd.,
Dioctyltin dilaurate, Nitto Chemical Industry

### Synthesis Example 1

A reactor equipped with a stirrer, a temperature controller, a reflux condenser, a dropping funnel, and a thermometer was charged with 32 parts by mass of propylene glycol monomethyl ether, and heating reflux was started. 90 parts by mass of 2-ethylhexyl acrylate and 10 parts by mass of glycidyl methacrylate were mixed to prepare a monomer mixture. A monomer mixture to which 0.10 parts by mass of 2,2′-azobis(isobutyronitrile) was added as a polymerization initiator was added dropwise to the reactor. After completion of the dropwise addition, the mixture was held at 85° C. for 4 hours. Next, the reaction temperature was increased to 120° C., 3.00 parts by mass of methacrylic acid and 5.00 parts by mass of methacrylic anhydride were added together with 1.00 parts by mass of triphenylphosphine as a catalyst, the mixture was held at 120° C. for 4 hours, and disappearance of methacrylic acid was confirmed by acid value measurement. Through the above-described steps, a propylene glycol monomethyl ether solution of the (meth)acrylic resin (A1) (solid content: 40 mass %) was obtained.

### Synthesis Examples 2 to 4

Propylene glycol monomethyl ether solutions of (meth)acrylic resins (A2) to (A4) (solid content: 40 mass %) were obtained in the same manner as in Synthesis Example 1, except that the compositions indicated in Table 1 were used.

### Comparative Synthesis Example 1

A reactor equipped with a stirrer, a temperature controller, a reflux condenser, a dropping funnel, and a thermometer was charged with 32 parts by mass of propylene glycol monomethyl ether, and heating reflux was started. 20 parts by mass of n-butyl acrylate, 70 parts by mass of 2-ethylhexyl acrylate, and 10 parts by mass of acrylic acid were mixed to prepare a monomer mixture. A monomer mixture to which 0.10 parts by mass of 2,2′-azobis(isobutyronitrile) was added as a polymerization initiator was added dropwise to the reactor. After completion of the dropwise addition, the mixture was held at 85° C. for 4 hours. Next, the reaction temperature was increased to 120° C., 20.00 parts by mass of 3,4-epoxycyclohexylmethyl methacrylate was added together with 1.00 parts by mass of triphenylphosphine as a catalyst, and the mixture was held at 120° C. for 4 hours. Through the above-described steps, a propylene glycol monomethyl ether solution of the (meth)acrylic resin (cAT) (solid content: 40 mass %) was obtained.

### Comparative Synthesis Example 2

A reactor equipped with a stirrer, a temperature controller, a reflux condenser, a dropping funnel, and a thermometer was charged with 32 parts by mass of ethyl acetate, and heating reflux was started. 20 parts by mass of methyl acrylate, 12 parts by mass of n-butyl acrylate, 50 parts by mass of 2-ethylhexyl acrylate, and 18 parts by mass of 2-hydroxyethyl acrylate were mixed to prepare a monomer mixture. A monomer mixture to which 0.10 parts by mass of 2,2′-azobis(isobutyronitrile) was added as a polymerization initiator was added dropwise to the reactor. After completion of the dropwise addition, the mixture was held under heating reflux for 4 hours. Next, the reaction temperature was lowered to 60° C., and a mixed liquid of 20.00 parts by mass of 2-isocyanatoethyl methacrylate and 0.10 parts by mass of dibutyltin dilaurate as a urethanization catalyst was added dropwise thereto. After completion of the dropwise addition, the reaction system was held at 60° C. for 4 hours to eliminate the isocyanato group. Through the above steps, an ethyl acetate solution of the (meth)acrylic resin (cA2) (solid content: 40 mass %) was obtained.

TABLE 1

| | | | | | | | Comparative | Comparative |
|---|---|---|---|---|---|---|---|---|
| | | | Synthesis | Synthesis | Synthesis | Synthesis | Synthesis | Synthesis |
| | | | Example 1 | Example 2 | Example 3 | Example 4 | Example 1 | Example 2 |
| (Meth)acrylic resin (A) | | | A1 | A2 | A3 | A4 | cA1 | cA2 |
| Monomer | Methyl acrylate | Part(s) | — | 35 | — | 35 | — | 20 |
| | n-Butyl acrylate | by mass | — | 35 | 18 | — | 20 | 12 |
| | 2-ethylhexyl acrylate | | 90 | — | 65 | 50 | 70 | 50 |
| | Glycidyl methacrylate | | 10 | — | — | — | — | — |
| | 4-Hydroxybutyl acrylate | | — | 30 | — | — | — | — |
| | glycidyl ether | | | | | | | |
| | 3,4-Epoxycyclohexylmethyl | | — | — | 17 | — | — | — |
| | methacrylate | | | | | | | |
| | 3,4-Epoxytricyclo [5.2.1.0^{2.6}] | | — | — | — | 15 | — | — |
| | decaneoxyethyl acrylate | | | | | | | |
| | Acrylic acid | | — | — | — | — | 10 | — |
| | 2-Hydroxyethyl acrylate | | — | — | — | — | — | 18 |
| | Total | | 100 | 100 | 100 | 100 | 100 | 100 |

| | | | | | | | |
|---|---|---|---|---|---|---|---|
| Methacrylic acid | Part(s) | 3.00 | 5.00 | 2.00 | 2.00 | — | — |
| Methacrylic anhydride | by mass | 5.00 | 9.00 | 6.00 | 4.00 | — | — |
| 3,4-Epoxycyclohexylmethyl methacrylate | | — | — | — | — | 20.00 | — |
| 2-Isocyanatoethyl methacrylate | | — | — | — | — | — | 20.00 |
| 2,2′-Azobis(isobutyronitrile) | | 0.10 | 0.10 | 0.10 | 0.10 | 0.10 | 0.10 |
| Triphenylphosphine | | 1.00 | 1.00 | 1.00 | 1.00 | 1.00 | — |
| Dioctyltin dilaurate | | — | — | — | — | — | 0.10 |
| Weight average molecular weight | — | 600000 | 400000 | 500000 | 600000 | 600000 | 500000 |
| Ethylenically unsaturated group equivalent | g/mol | 759.43 | 652.88 | 1070.02 | 1412.97 | 1196.12 | 930.90 |
| Hydroxyl value | mgKOH/g | 36.24 | 28.54 | 12.05 | 12.28 | 46.90 | 12.20 |
| Glass transition temperature (Tg) | ° C. | −63 | −37 | −51 | −32 | −56 | −47 |

Raw materials used for the preparation of pressure sensitive adhesive compositions are indicated below.

### Photopolymerization Initiator (B):

TPO: 2,4,6-Trimethylbenzoyldiphenylphosphine oxide (IGM RESINS B.V., trade name: Omnirad TPO)
   Crosslinking agent (C)
L-45E: Tolylene diisocyanate adduct of trimethylolpropane (Tosoh Corporation, trade name: Coronate L-45E)

### Preparation of Pressure Sensitive Adhesive Composition

Ethyl acetate as a diluent solvent was added to the solutions containing the (meth)acrylic resins (A1) to (A4) and (cA1) and (cA2) obtained in Synthesis Examples 1 to 4 and Comparative Synthesis Examples 1 and 2 respectively, and the contents of the (meth)acrylic resins (A1) to (A4) and (cA1) and (cA2) were adjusted to 30 mass %. Using the solution, a pressure sensitive adhesive composition was obtained by the following method.

The (meth)acrylic resin (A), the photopolymerization initiator (B), and the crosslinking agent (C) indicated in Table 2 were added to plastic containers in the contents (parts by mass) indicated in Table 2 in a room shielded from active rays and stirred to obtain pressure sensitive adhesive compositions (1) to (4), (c1), and (c2). The numerical value of the (meth)acrylic resin (A) in Table 2 is the solid content of the used solution, that is, the amount (parts by mass) of the (meth)acrylic resin used.

### [Example 1] Preparation of Pressure Sensitive Adhesive Sheet

As a separator, a silicone-based easy-release PET film (Toyobo Co., Ltd., product name: E7006, 25 μm thick) was prepared, and the pressure sensitive adhesive composition (1) was applied to the release-treated surface using an applicator to attain a thickness of 20 μm after curing, and heat-dried at 100° C. for 2 minutes to form a pressure sensitive adhesive layer. Next, a PO film having a thickness of 90 μm was prepared as a sheet-shaped substrate. The PO film was attached to the pressure sensitive adhesive layer using a rubber roller, and the corona-treated surface of the PO film adhered to the exposed surface of the pressure sensitive adhesive layer. The resultant product was cured in an oven at 40° C. for 3 days to crosslink and set the pressure sensitive adhesive layer, thereby obtaining a pressure sensitive adhesive sheet of Example 1.

### [Examples 2 to 4 and Comparative Examples 1 and 2] Preparation of Pressure Sensitive Adhesive Sheet

Pressure sensitive adhesive sheets of Examples 2 to 4 and Comparative Examples 1 and 2 were obtained in the same manner as in Example 1 except that the pressure sensitive adhesive composition indicated in Table 2 was used instead of the pressure sensitive adhesive composition (1).

### Preparation of Dicing/Die-Bonding Integrated Film

A cover film on one side of a die-bonding film (DAF) (FH-D25T-50, Showa Denko Materials Co., Ltd.) having a film thickness of 25 μm or 10 μm in which both surfaces of an adhesive layer were protected by the cover film was released to expose the adhesive layer. This adhesive layer and the ultraviolet curable pressure sensitive adhesive layer of each of the pressure sensitive adhesive sheets of Examples 1 to 4 and Comparative Examples 1 and 2, from which the easy-release PET film had been released to expose the ultraviolet curable pressure sensitive adhesive layer, were bonded together with a rubber roller. The product was let stand at room temperature for 1 day to obtain a dicing/die-bonding integrated film.

### Evaluation

### (1) Measurement of Adhesive Strength Before UV Irradiation (30° Peel Strength)

As described below, the adhesive strength of the pressure sensitive adhesive sheets according to Examples and Comparative Examples to a die-bonding film (DAF) was evaluated by measuring the 30° peel strength. A sample having a width of 25 mm and a length of 100 mm was cut out from the dicing/die-bonding integrated film. The cover film of the dicing/die-bonding integrated film to which the pressure sensitive adhesive sheet was not attached was released, and the adhesive layer was attached to a polycarbonate plate using a double-sided tape to obtain a sample for measuring adhesive strength. The peel strength of the pressure sensitive adhesive sheet to the die-bonding film was measured using a tensile tester (VPA-H200, Kyowa Interface Science Co., Ltd.). The measurement conditions were a peeling angle of 30° and a tensile speed of 600 mm/min. The storage of the sample and the measurement of the peel strength were performed in an environment at a temperature of 23° C. and a relative humidity of 40%. The results are indicated in Table 2.

(2) Measurement of Adhesive Strength after UV Irradiation (30° Peel Strength)

Ultraviolet rays (UV) were applied to a dicing/die-bonding integrated film, at an irradiation amount of 300 mJ/cm², from the surface, on the side of the substrate, of the pressure sensitive adhesive sheet to afford a sample for measuring the adhesive strength after UV irradiation. A conveyor type ultraviolet irradiation device (EYE GRAPHICS COMPANY, 2 KW lamp, 80 W/cm) was used for UV irradiation. Thereafter, the peel strength of the pressure sensitive adhesive sheet to the die-bonding film was measured in the same manner as in the measurement of the adhesive strength before UV irradiation (300 peel strength). The results are indicated in Table 2.

### (3) Pickup Property

### (i) Preparation of Sample for Pickup Properties Evaluation

A protective tape (BG tape) was attached to a surface of a silicon wafer (diameter: 12 inch, thickness: 775 μm). Thereafter, stealth dicing of the silicon wafer was performed. That is, a modified layer was formed inside the silicon wafer by irradiating a surface (back surface) of the silicon wafer opposite to the side to which the BG tape was attached with laser light under the following conditions.

### Stealth Dicing Conditions

Stealth dicing device: DFL7361 (DISCO Corporation)
Laser oscillator type: Q-switched semiconductor-excited solid-state laser
Wavelength: 1342 nm
Frequency: 90 kHz
Output: 1.7 W
The number of passes: 2
Chip size: 10 mm×10 mm
Dicing speed: 700 mm/second

The silicon wafer after stealth dicing was polished to have a thickness of 30 μm. A grinder polisher device (DGP8761, DISCO Corporation) was used for polishing. The adhesive layer of the dicing/die-bonding integrated film was attached to the polished silicon wafer under the following conditions with the surface on the substrate side of the pressure sensitive adhesive sheet facing a dicing ring. Thereafter, the BG tape was released from the surface of the silicon wafer.

Attachment conditions
Attachment device: DFM2800 (DISCO Corporation)
Attachment temperature: 70° C.
Attachment speed: 10 mm/s
Attachment tension level: level 6

Subsequently, a die separator (DDS2300, DISCO Corporation) was used to cool and expand under the following conditions. Thereafter, the substrate layer (PO film) of the dicing/die-bonding integrated film was heat-shrunk under the following conditions. Through these steps, the silicon wafer and the adhesive layer were singulated into a plurality of adhesive piece-attached chips (size: 10 mm×10 mm).

### Cooling Expanding Conditions

Cooling temperature: −15° C.
Cooling time: 120 seconds
Push-up length: 12 mm
Push-up speed: 200 mm/second
Retention time after push-up: 3 seconds

### Heat Shrink Conditions

Heater temperature: 220° C.
Heater rotation speed: 5°/second
Push-up length: 8 mm
Tape cooling waiting time: 10 seconds

After the silicon wafer and the adhesive layer were singulated, the ultraviolet curable pressure sensitive adhesive layer was irradiated with ultraviolet rays from the surface, on the substrate side, of the pressure sensitive adhesive sheet under the following conditions. As a result, the ultraviolet curable pressure sensitive adhesive layer was cured to reduce the adhesive strength to the adhesive layer.

### Ultraviolet Irradiation Conditions

Illuminance of ultraviolet ray: 100 mW/cm²
Irradiation amount of ultraviolet ray: 150 mJ/cm²

### Pickup Property Evaluation

100 adhesive piece-attached chips were picked up under the following conditions and evaluated according to the following criteria. The results are indicated in Table 2.

### Pickup Conditions

Die bonder device: DB-830P (FASFORD TECHNOLOGY CO., LTD.)
Push-up pin: EJECTOR NEEDLE SEN2-83-05 (size: 0.7 mm, tip shape: hemisphere having radius of 350 μm, Micromechanics)
Push-up height: 250 μm
Push-up speed: 1 mm/second
Number of push-up pins: 9

### Evaluation Criteria

A: Pickup success rate was 100%.
B: Pickup success rate was 80% or more and less than 100%.
C: Pickup success rate was 60% or more and less than 80%.

TABLE 2

| | | | Example | Example | Example | Example | Comparative | Comparative |
|---|---|---|---|---|---|---|---|---|
| | | | 1 | 2 | 3 | 4 | Example | Example 2 |
| Pressure sensitive adhesive composition | | | 1 | 2 | 3 | 4 | c1 | c2 |
| (Meth)acrylic | A1 | Part(s) | 100 | — | — | — | — | — |
| resin (A) | A2 | by mass | — | 100 | — | — | — | — |
| | A3 | | — | — | 100 | — | — | — |
| | A4 | | — | — | — | 100 | — | — |
| | cA1 | | — | — | — | — | 100 | — |
| | cA2 | | — | — | — | — | — | 100 |
| Photopolymerization | TPO | | 1.0 | 1.0 | 1.0 | 1.0 | 1.0 | 1.0 |
| initiator (B) | | | | | | | | |
| Crosslinking agent (C) | L-45E | | 1.0 | 1.0 | 1.0 | 1.0 | 1.0 | 1.0 |

| Thickness (μm) of pressure sensitive adhesive | | 20 | 20 | 20 | 20 | 20 | 20 |
|---|---|---|---|---|---|---|---|
| layer of pressure sensitive adhesive sheet | | | | | | | |
| Against DAF | Adhesive strength before UV irradiation | 11.5 | 9.0 | 10.5 | 12.0 | 10.0 | 8.0 |
| (25 μm) | (30° peel strength) (N/25 mm) | | | | | | |
| | Adhesive strength after UV irradiation | 0.65 | 0.60 | 0.75 | 0.70 | 2.50 | 1.90 |
| | (30° peel strength) (N/25 mm) | | | | | | |
| | Pickup property | A | A | A | A | B | B |
| Against DAF | Adhesive strength before UV irradiation | 12.0 | 10.0 | 11.0 | 12.0 | 10.0 | 7.5 |
| (10 μm) | (30° peel strength) (N/25 mm) | | | | | | |
| | Adhesive strength after UV irradiation | 0.60 | 0.60 | 0.65 | 0.70 | 3.00 | 2.50 |
| | (30° peel strength) (N/25 mm) | | | | | | |
| | Pickup property | A | A | A | A | C | C |

In all of Examples 1 to 4, the adhesive strength before UV irradiation was good, the adhesive strength was sufficiently reduced after UV irradiation, and the pickup properties were rated as A, which was good. In contrast, in Comparative Example 1, the adhesive strength after UV irradiation was not sufficiently reduced, and the pickup success rate was low. This is assumed to be because the acrylic acid-derived carboxy group of the (meth)acrylic resin used in Comparative Example 1 improves the adhesive strength to the adherend, and adversely affects the release property after UV irradiation. In Comparative Example 2, similarly, the adhesive strength after UV irradiation was not sufficiently reduced, and the pickup success rate was low. This is assumed to be because of 2-isocyanatoethyl methacrylate that was used for the synthesis of the (meth)acrylic resin used in Comparative Example 2. That is, it is assumed that when 2-isocyanatoethyl methacrylate is used in the addition reaction, a dimer is generated as an impurity, wettability of the pressure sensitive adhesive layer to the adherend is enhanced, and a phenomenon in which the dimer moves to the adherend occurs. As a result, it is assumed that after the UV irradiation, the moved dimer is crosslinked with the (meth)acrylic resin of the pressure sensitive adhesive layer, which adversely affects the release property after UV irradiation and pickup properties.

### INDUSTRIAL APPLICABILITY

The present invention provides a pressure sensitive adhesive composition which has a sufficient adhesive strength to an adherend and has improved release property from the adherend in which the adhesive strength is sufficiently reduced upon UV irradiation after completion of processing steps. A pressure sensitive adhesive layer, which is a thermally cured product of the pressure sensitive adhesive composition, can be preferably used as a removable pressure sensitive adhesive sheet, particularly as a pressure sensitive adhesive layer of a dicing/die-bonding integrated film.

1. An pressure sensitive adhesive composition, comprising:
a (meth)acrylic resin (A);
a photopolymerization initiator (B); and
a crosslinking agent (C),
the (meth)acrylic resin (A) containing structural units represented by the following Formulas (1) to (3) and optionally containing a structural unit represented by the following Formula (4): 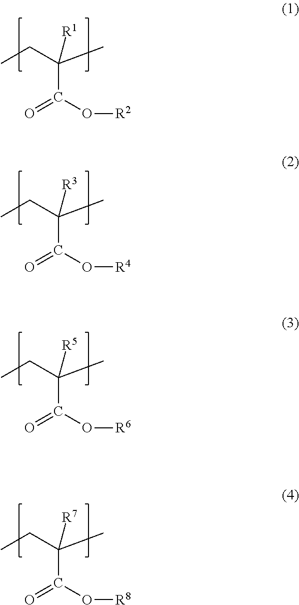
wherein in Formula (1), R¹ represents a hydrogen atom or a methyl group, and R² represents an alkyl group having from 1 to 20 carbon atoms, in Formula (2), R³ represents a hydrogen atom or a methyl group, and R⁴ represents a group having: a hydroxy group bonded to a carbon atom; and a residue bonded to a carbon atom adjacent to said carbon atom, the residue being obtained by removing a hydrogen atom from a carboxy group of an unsaturated monocarboxylic acid, in Formula (3), R⁵ represents a hydrogen atom or a methyl group, and R⁶ represents a group having: a residue bonded to a carbon atom, the residue being obtained by removing a hydrogen atom from a carboxy group of an unsaturated monocarboxylic acid; and a residue bonded to a carbon atom adjacent to said carbon atom, the residue being obtained by removing a hydrogen atom from a carboxy group of an unsaturated monocarboxylic acid, and in Formula (4), R⁷ represents a hydrogen atom or a methyl group, and R⁸ represents a group containing an epoxy group.

2. The pressure sensitive adhesive composition according to claim 1, wherein an ethylenically unsaturated group equivalent of the (meth)acrylic resin (A) is from 350 to 4000 g/mol.

3. The pressure sensitive adhesive composition according to claim 1, wherein a percentage of a total of the structural units represented by Formulas (2) to (4), based on all the structural units of the (meth)acrylic resin (A), is from 1 to 50 mol %.

4. The pressure sensitive adhesive composition according to claim 1, wherein a percentage of a total of the structural units represented by Formulas (2) and (3) of the (meth)acrylic resin (A), relative to a total of the structural units represented by Formulas (2) to (4), is from 50 to 100 mol %.

5. The pressure sensitive adhesive composition according to claim 1, wherein a glass transition temperature (Tg) of the (meth)acrylic resin (A) is from −80° C. to 0° C.

6. The pressure sensitive adhesive composition according to claim 1, wherein the residue obtained by removing a hydrogen atom from a carboxy group of an unsaturated monocarboxylic acid is a (meth)acryloyloxy group.

7. The pressure sensitive adhesive composition according to claim 1, wherein each of the carbon atoms, to which the hydroxy group or the residue obtained by removing a hydrogen atom from a carboxy group of an unsaturated monocarboxylic acid is bonded in Formulas (2) and (3) has one or two hydrogen atoms.

8. The pressure sensitive adhesive composition according to claim 1, wherein a hydroxyl value of the (meth)acrylic resin (A) is from 1 to 60 mgKOH/g.

9. The pressure sensitive adhesive composition according to claim 1, wherein a weight average molecular weight of the (meth)acrylic resin (A) is from 100000 to 1000000.

10. The pressure sensitive adhesive composition according to claim 1, wherein the crosslinking agent (C) is a polyisocyanate.

11. An ultraviolet curable pressure sensitive adhesive layer, which is a thermally cured product of the pressure sensitive adhesive composition according to claim 1.

12. A pressure sensitive adhesive sheet, comprising:
the ultraviolet curable pressure sensitive adhesive layer according to claim 11; and
a substrate layer.

13. A dicing/die-bonding integrated film, comprising:
a substrate layer, the ultraviolet curable pressure sensitive adhesive layer according to claim 11, and an adhesive layer in this order.

14. A method for manufacturing a semiconductor device, the method comprising dicing a semiconductor by using the dicing/die-bonding integrated film according to claim 13.
